(19) United States
(12) Patent Application Publication
(10) Pub. No.: US 2024/0037297 A1
(43) Pub. Date: Feb. 1, 2024

(54) System to Determine the State of an Orbiting Object Using Multi-Model Ensemble Techniques for Drag and Methods Thereof

(71) Applicant: West Virginia University Board of Governors on Behalf of West Virginia University, Morgantown, WV (US)

(72) Inventors: Piyush M. Mehta, Bridgeville, PA (US); Richard J. Licata, Morgantown, WV (US); Smriti Nandan Paul, Morgantown, WV (US)

(21) Appl. No.: 18/225,269

(22) Filed: Jul. 24, 2023

Related U.S. Application Data
(60) Provisional application No. 63/391,356, filed on Jul. 22, 2022.

(51) Int. Cl. G06F 30/27; B64G 3/00; G06F 17/18

(52) U.S. Cl. CPC G06F 30/27; B64G 3/00; G06F 17/18

(57) ABSTRACT

The present disclosure relates to the quantification and propagation of orbital state uncertainties and accurately determining an orbit state of an orbiting object using multi-model ensemble analysis. Input data (e.g., solar indices, geomagnetic indices, space weather parameters, temporal parameters, etc.) associated with the solar environment and orbiting object can be provided as inputs to multiple trained density prediction models. The trained density prediction models can be configured to output atmospheric density data associated with the orbiting object (e.g., satellite). Using orbit propagation for the respective atmospheric density data, orbit data (e.g., position, velocity) can be predicted. The predicted orbit data associated with the multiple density prediction models can then be analyzed in an ensemble approach to accurately predict the orbit state of the orbiting object.

### CROSS REFERENCE TO RELATED APPLICATION

This application claims benefit of U.S. Provisional Application No. 63/391,356 filed Jul. 22, 2022, entitled “SYSTEM TO DETERMINE THE STATE OF AN ORBITING OBJECT USING MULTI-MODEL ENSEMBLE TECHNIQUES FOR DRAG AND METHODS THEREOF,” which is hereby incorporated by reference in its entirety for all purposes.

### BACKGROUND

In recent decades, ambitious satellite mega-constellation projects such as SpaceX's Starlink constellation, OneWeb satellite constellation, and others, as well as affordable access to space, have resulted in an exponential growth of objects in the low Earth orbit (LEO) region. There are no signs of a reversal of this trend, as tens of thousands of satellites are tentatively planned for launch in the near future. This proliferation increases the risk of collisions between active space assets and space debris or between debris and debris, threatening the sustainability of this commercially and scientifically critical near-Earth region. To address this sustainability challenge better space domain awareness (SDA) and space traffic management (STM) measures are needed. A particularly important aspect of SDA/STM is the conjunction assessment that involves computing the probability of collision between two space objects, which is critical for operational decisions such as the firing of thrusters or differential drag application for orbit modification. Reliable estimates of the uncertainties in the orbital state of a space object are required for determining the probability of collision.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 illustrates an example of an orbit state prediction system of the present disclosure in accordance to various embodiments.

FIG. 2 illustrates an example schematic of a traditional Monte Carlo approach for orbit uncertainty propagation according to various embodiments of the present disclosure.

FIG. 3 illustrates an example schematic of modified approach to the traditional Monte Carlo approach of FIG. 2 for orbit uncertainty propagation according to various embodiments of the present disclosure.

FIG. 4 illustrates an example schematic of modified approach to the Monte Carlo approaches of FIGS. 2 and 3 for orbit uncertainty propagation according to various embodiments of the present disclosure.

FIGS. 5A-5J illustrate graphical representations of the traditional and modified Monte Carlo approaches of FIGS. 2-4 according to various embodiments of the present disclosure.

FIGS. 6A-6D illustrate graphical representations of the orbit state probability density function (PDF) for the along-track direction using the super ensemble approach according to various embodiments of the present disclosure.

FIG. 7 illustrates graphical representation of a comparison between the Monte Carlo and consider covariance sigma point (CCSP) filter-based methods of orbit uncertainty propagation according to various embodiments of the present disclosure.

FIG. 8 is an example flowchart that includes portions of functionality of orbit state prediction system executed in a computing environment according to various embodiments of the present disclosure.

FIG. 9 is a schematic block diagram that provides one example illustration of a computing environment according to various embodiments of the present disclosure.

### DETAILED DESCRIPTION

The present disclosure relates to the quantification and propagation of orbital state uncertainties. For objects in the low Earth orbit region, uncertainty in atmospheric density estimation is an important source of orbit prediction error, which is critical for space traffic management activities such as the satellite conjunction analysis. The present disclosure relates to the evolution of orbit error distribution in the presence of atmospheric density uncertainties, which are modeled using probabilistic machine learning techniques. In particular, the present disclosure relates to accurately determining an orbit state of an orbiting object using multi-model ensemble analysis. In various examples, input data (e.g., solar indices, geomagnetic indices, space weather parameters, temporal parameters, etc.) associated with the space environment and orbiting object can be provided as inputs to multiple trained density prediction models. The trained density prediction models can be configured to output atmospheric density data associated with the orbiting object (e.g., satellite). Using orbit propagation for the respective atmospheric density data, orbit data (e.g., position, velocity) can be predicted. The predicted orbit data associated with the multiple density prediction models can then be analyzed in an ensemble approach to accurately determine the orbit state of the orbiting object.

The primary sources of errors in orbit prediction problems are—(a) initial state uncertainties and (b) dynamical uncertainties. The first source of error refers to inadequate knowledge about the initial orbital state (e.g., position and velocity) that arises from uncertainties in the measurements (obtained using ground-based or space-based sensors), which are used in the orbit determination (OD) process. The second source of error emanates from incomplete knowledge about the dynamical form of the perturbation forces, uncertainties in the dynamical parameters (e.g., atmospheric density, drag coefficient, reflection coefficients, and others), and from missing low-order forces (e.g., Lorentz force, Earth albedo, etc.) that are often not included in the modeling. The present disclosure focuses on the effects of uncertainties in atmospheric density, which is one of the largest sources of dynamical uncertainties for objects in the LEO region. The uncertainty in atmospheric density manifests itself through the atmospheric drag force, which is given as:

$${\vec{a}}_{D} = - \frac{1}{2} ρ \frac{{C}_{D} {A}_{p r o j}}{m} {v}_{rel} {\vec{v}}_{τ e l} \qquad ( 1 )$$

where ρ is the atmospheric density, C_{D} is the drag coefficient, Aₚᵣₒⱼ is the projected area of the satellite perpendicular to the flow direction, \vec{v}ᵣₑₗ is the velocity of the satellite relative to the atmosphere, and vᵣₑₗ is the magnitude of \vec{v}ᵣₑₗ. The satellite mass is usually known from the operators and constant for a non-maneuvering satellite, but all other parameters can have uncertainties. Except for the atmospheric neutral mass density, additional uncertainties in other drag parameters are not addressed.

Atmospheric density and its associated uncertainty have a complex dependency upon the selected atmospheric model, solar irradiance in the extreme ultraviolet (EUV) and far ultraviolet (FUV) spectral ranges, geomagnetic indices, location, epoch, and various other factors, which make it a challenging problem to estimate the density. The difficulty is particularly amplified during large geomagnetic storms and can even lead to the loss of satellites. Several thermospheric mass density models have been proposed over the years. These density models can either be categorized as physical models (those that solve fluid equations) or empirical models (those that represent average behavior of atmospheric observations in a parameterized mathematical formulation). However, most density models in existence, including the operational High Accuracy Satellite Drag Model (HASDM) system used by the United States Space Force (USSF), do not provide an estimate of the uncertainty in their predictions.

Little attention has been paid to the direct quantification of the uncertainty in atmospheric density models. Using Gaussian Processes (GPs), one known framework uses uncertainty quantification of NRLMSISE-00 (Naval Research Laboratory Mass Spectrometer and Incoherent Scatter Radar Extended) and JB2008 (Jacchia-Bowman) neutral mass density models. Another known framework uses statistical data binning techniques combined with least square fitting approaches to provide an uncertainty quantification model for the DTM2020 (Drag Temperature Model) thermosphere density model. In another framework, the Monte Carlo dropout technique, a Bayesian approximation of the Gaussian Process, is leveraged to develop a probabilistic density model utilizing the Space Environment Technologies (SET) High Accuracy Satellite Drag Model (HASDM) density database.

More recently, three machine learning models have been developed that directly predict mean and standard deviation (as opposed to an “ensemble-like” approach followed in the computationally expensive Monte Carlo dropout technique). The first model, the HASDM-ML-DP (ML: machine learning; DP: direct probability prediction), is based on the SET HASDM database. The second model, the CHAMP-ML-DP, is based on the accelerometer data collected by the Challenging Minisatellite Payload (CHAMP) satellite. The third model, the MSIS-UQ-DP, is based on combined data from the CHAMP, Gravity Recovery and Climate Experiment (GRACE), Swarm A, and Swarm B satellites. According to various examples, the density models used to estimate orbit and/or orbit parameters (e.g., position, velocity) include the HASDM-ML-DP, CHAMP-ML-DP, and MSIS-UQ-DP thermospheric density models. These models are discussed in further detail in Licata, R. J., Mehta, P. M., 2022b. Uncertainty quantification techniques for data-driven space weather modeling: thermospheric density application. Sci. Rep. 12 (7256) (hereinafter “Licata and Mehta 2022b”) and Licata, R. J., Mehta, P. M., Weimer, D. R. et al., 2022b. MSIS-UQ: Calibrated and enhanced NRLMSIS 2.0 model with uncertainty quantification. Space Weather, 20(11), e2022SW003267 (hereinafter “Licata, et al. 2022b”), which are both incorporated by reference in their entireties.

The effects of atmospheric density uncertainty on the orbital state uncertainties or derived quantities such as the probability of collision have been investigated. In some example implementations, a first-order Gauss-Markov process is used to model atmospheric density uncertainty in an Extended Kalman Filter (EKF) framework for orbit determination. Other example implementations present an Ornstein-Uhlenbeck process-based framework that uses the intrinsic difference between various atmospheric density models to characterize the uncertainty in atmospheric density and subsequently study its effect on orbit prediction. Some example implementations use analytic expressions for in-track position errors due to EUV forecast errors modeled using the Brownian motion process. In some examples, the effects of uncertainty in F_{10.7} and Ap space weather drivers on the probability of collision have been implemented. Using Proper Orthogonal Decomposition (POD), some known implementations use a dynamic reduced-order density model, which is then used in a Kalman filtering framework for uncertainty propagation. In various examples, while the present disclosure estimates uncertainties for the calculation of the probability of collision, none of the known implementations described use an atmospheric density model that explicitly provides the uncertainty in its estimate.

The goal of the present disclosure is to develop an ensemble methodology and system that combines the epistemic uncertainties predicted by the HASDM-ML-DP, CHAMP-ML-DP, MSIS-UQ-DP, and/or other density models to characterize the uncertainty in the orbital states of a space object. To address the fact that no model is perfect, and the model skill changes with conditions, the proposed ensemble modeling approach provides a higher degree of covariance realism.

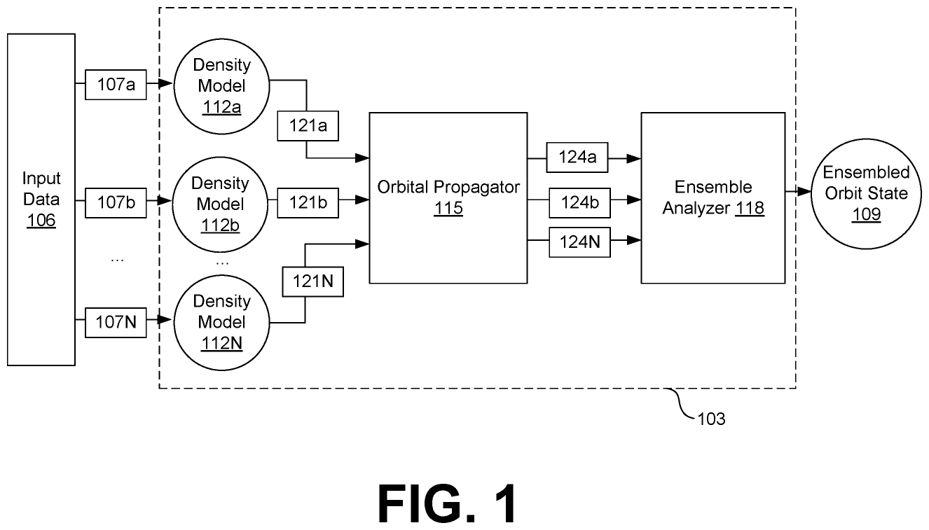

FIG. 1 illustrates a schematic illustrating a computing environment for the quantification and propagation of orbital state uncertainties according to various examples of the present disclosure. In particular, shown in FIG. 1 is an orbit state prediction system 103 that can take input data 106 as inputs to determine an ensembled orbit state 109 for an object (e.g., a satellite) orbiting in space. In various examples, the input data can comprise solar indices/proxies (e.g., S₁₀, M₁₀, Y₁₀, F₁₀), geomagnetic indices (e.g., Ap, ap and Dst), temporal parameters (e.g., day of the year (doy), time of day (UT)), space weather parameters (e.g., velocity, temperature, etc.), and/or other inputs as can be appreciated. In various examples, these inputs can be extracted from a database and/or separately collected/calculated as can be appreciated.

In various examples, the orbit state prediction system 103 can comprise one or more density prediction models 112 (e.g., 112a, 112b, . . . 112N), an orbital propagator 115, and an ensemble analyzer 118.be In various examples, the density prediction models can comprise stochastic density models configured to predict or otherwise estimated atmospheric density based at least in part on an analysis of the input data 106. For example, as will be described in greater detail, the density prediction models 112 can comprise the HASDM-ML-DP, CHAMP-ML-DP, MSIS-UQ-DP, and/or other density prediction model. In various examples, each of the different types of density prediction models can have strengths and weaknesses associated with the atmospheric density and uncertainty predictions. In addition, each of the different types of density prediction models can be inputted with a different subset 107 (e.g., 107a, 107b, 107N) of input data 106. For example, the input subset 107 for the HASDM-ML-DP may comprise eight solar indices/proxies, sixteen (16) geomagnetic indices (time history for ap and Dst), and four temporal parameters. Conversely, the input subset 107 for the CHAMP-ML-DP model may comprise eight solar indices/proxies, three geomagnetic indices, and eight spatiotemporal parameters.

In various examples, the output of each of the density prediction models 112 can comprise density data 121 (e.g., 121a, 121b, . . . 121N). In various examples, the density data 121 can comprise a density map, the mean and standard deviation of the atmospheric density, uncertainty density data, and/or other type of data representing the atmospheric density in view of an analysis of the input data 106. In various examples, the density data 121 obtained from each of the density prediction models 112 can undergo orbital propagation to predict orbit data 124 (e.g., 124a, 124b, . . . 124N). In various examples, the orbit data 124 can comprise the orbit state probability density function (PDF) associated with each of the different density prediction models 112. In various examples, the density data 121 can be provided as an input to an orbital propagator 115 that is configured to analyze the density data 121 to predict orbit states and generate orbit data 124. As will be discussed in greater detail, the orbital propagator can analyze the density data 121 using Monte Carlo approaches, a consider covariance sigma point (CCSP) filter, and/or other approaches. In various examples, the Monte Carlo approaches can comprise Monte Carlo orbit propagation algorithms that not only account for the effect of density uncertainty but also preserve spatiotemporal correlation for the density. Similarly, the CCSP filter can be used for orbit uncertainty propagation while capturing the effects of atmospheric density uncertainty.

In various examples, the predicted orbit data 124 that is output from the orbital propagator for each of the density models 112 can be provided to an ensemble analyzer 118 to accurately predict and/or generate the ensembled orbit state 109. In various examples, the ensemble analyzer 118 can comprise a Gaussian mixture model configured to analyze and combine the orbit data 124 associated with each of the density models 112 to predict an ensembled orbit state 109 (e.g., the orbit state probability density function (PDF)).

### Stochastic Density Models

### HASDM-ML-DP Density Model

The HASDM is a proprietary operational thermospheric density framework used by the USSF Combined Space Operations Center. Using the so-called Dynamic Calibration of the Atmosphere (DCA) algorithm, the HASDM framework estimates thirteen (13) global density correction parameters to provide near real-time corrections to the base JB2008 thermospheric density model. The computation of the global density correction field relies on the observed drag effects on a large number of calibration satellites in the LEO region.

Recently, as part of an open-access initiative for scientific studies, SET has publicly made available the SET HASDM density database consisting of data from Jan. 1, 2000 through Dec. 31, 2019. The publicly available data has a cadence of three hours and a resolution of 15° longitude, 10° latitude, and 25 km altitude ranging between 175-825 km. The database consists of 58,440 samples. This data has been used to generate a deep neural network (DNN)-based framework that directly predicts the mean and standard deviation of parameters of interest, which are subsequently processed through an inverse function to obtain estimates of the mean and standard deviation of the atmospheric density. The inputs for their DNN, motivated by the drivers for the JB2008 density model, consist of eight solar indices/proxies, sixteen (16) geomagnetic indices (time history for ap and Dst), and four temporal parameters.

The SET HASDM database has 12,312 outputs (combination of twenty-four (24) longitude values, nineteen (19) latitude values, and twenty-seven (27) altitude values) at each epoch, which would make any regression efforts a computationally challenging task. To facilitate computational feasibility, principal component analysis (PCA) can be used to obtain a reduced-order model (ROM). PCA can be used to perform the following decomposition:

$$x ( s , t ) = \overline{x} ( s ) ) + \overline{x} ( s , t ) \qquad ( 2 a )$$

$$\overline{x} ( s , t ) = {{\sum }_{i = 1}}^{10} [ {α}_{j} ( t ) {U}_{j} ( s ) ] \qquad ( 2 b )$$

where x(s, t) is the log-transformed HASDM density, x̅(s) is the mean dependent only on the spatial coordinates, αⱼ (t) are the temporal PCA coefficients, and Uⱼ (s) are the orthogonal modes or basis functions. In the HASDM-ML-DP, the mean and standard deviation of the ten (10) PCA coefficients is predicted (i.e., the output dimension of the ML model is twenty (20)). The predicted coefficients are multiplied by matrix U (formed from the orthogonal modes of variation), followed by the addition of the spatial mean to decode back to log density. A Monte Carlo simulation can be carried out, where multiple sets of PCA coefficients are sampled from their distribution, followed by the mentioned multiplication/addition operation to obtain a stochastic estimate of the log density.

### CHAMP-ML-DP Density Model

CHAMP was a German satellite launched on Jul. 15, 2000 and remained in orbit for a decade before re-entering the Earth's atmosphere in 2010. Its orbit was near-circular, near-polar (i˜87°), and an initial altitude of 460 km was chosen. The STAR accelerometer on board the CHAMP satellite measured the resultant non-gravitational forces experienced by the satellite. By modeling out the effects of atmospheric lift, solar radiation pressure, albedo, and infrared radiation pressure, estimates of acceleration due to atmospheric drag are derived. Thereafter, a drag coefficient model (C_{D}_{_{Sutton}}) and a satellite geometry (representative of the satellite cross-sectional area, A_{Sutton}) are used to obtain an estimate of the neutral thermospheric density (P_{Sutton}). Using a higher fidelity satellite geometry (A_{Mehta}) and an improved drag coefficient model (C_{D}_{_{Mehta}}), the density estimates can be scaled to obtain a new set of density estimates for the CHAMP satellite as:

$${ρ}_{M e h t a} = \frac{{C}_{{D}_{S u t t o n}} {A}_{s u t t o n}}{{C}_{{D}_{M e h t a}} {A}_{M e h t a}} {ρ}_{S u t t o n} \qquad ( 3 )$$

The CHAMP database spans from Jan. 1, 2002 through Feb. 22, 2010. The CHAMP database is provided by Piyush M. Mehta, Andrew C. Walker, Eric K. Sutton, and Humberto C. Godinez. New density estimates derived using accelerometers on-board the CHAMP and GRACE satellites. Space Weather, 15, 558-576, doi:10.1002/2016SW001562 (hereinafter “Mehta”) which is incorporated by reference in its entirety. The data has a cadence of ten seconds, making it a total of more than twenty-five million samples. The CHAMP-ML-DP is a DNN-based regression model that utilizes density data provided by Mehta. The input data for the CHAMP-ML-DP consists of eight solar indices/proxies, three geomagnetic indices, and eight spatiotemporal parameters, and the output data consists of the mean and standard deviation of the atmospheric density. More details on the input and the training of the model can be found in Licata and Mehta 2022b. The main distinction between the CHAMP-ML-DP and the HASDM-ML-DP is that the CHAMP-ML-DP is based on local measurements, whereas the HASDM-ML-DP is based on global measurements.

### MSIS-UQ-DP Density Model

The Naval Research Laboratory updated the empirical NRLMSISE-00 density model to release a new version called NRLMSIS 2.0 in 2021. Changes are incorporated in the fundamental formulations, and substantial additional measurements are included to make NRLMSIS 2.0 more accurate than the original version. The density estimates from NRLMSIS 2.0 depend upon the exospheric temperature. Recently, a feed-forward deep neural network model, MSIS-UQ-DP, has been developed that performs uncertainty quantification for the exospheric temperature, which in turn is fed into the NRLMSIS 2.0 model to obtain uncertainty estimates for the density. To develop the MSIS-UQ-DP model, a database of 81 million exospheric temperatures is used. These exospheric temperatures are computed using a binary search method such that the densities from NRLMSIS 2.0 match density estimates of the CHAMP, GRACE-A, Swarm A, and Swarm B satellites. CHAMP and GRACE-A density estimates are obtained from accelerometer measurements, whereas the Swarm density estimates are obtained from orbit determination using the onboard Global Positioning System (GPS) receivers. The input data for the MSIS-UQ-DP model consists of twenty-one spatio temporal parameters. The MSIS-UQ-DP model provides a well-calibrated uncertainty estimate and has a superior mean absolute error performance compared to the NRLMSIS 2.0 and HASDM density models.

### Monte Carlo Methods for Orbit Uncertainty Propagation

‘Traditional’ Monte Carlo Method with a High Sampling Frequency

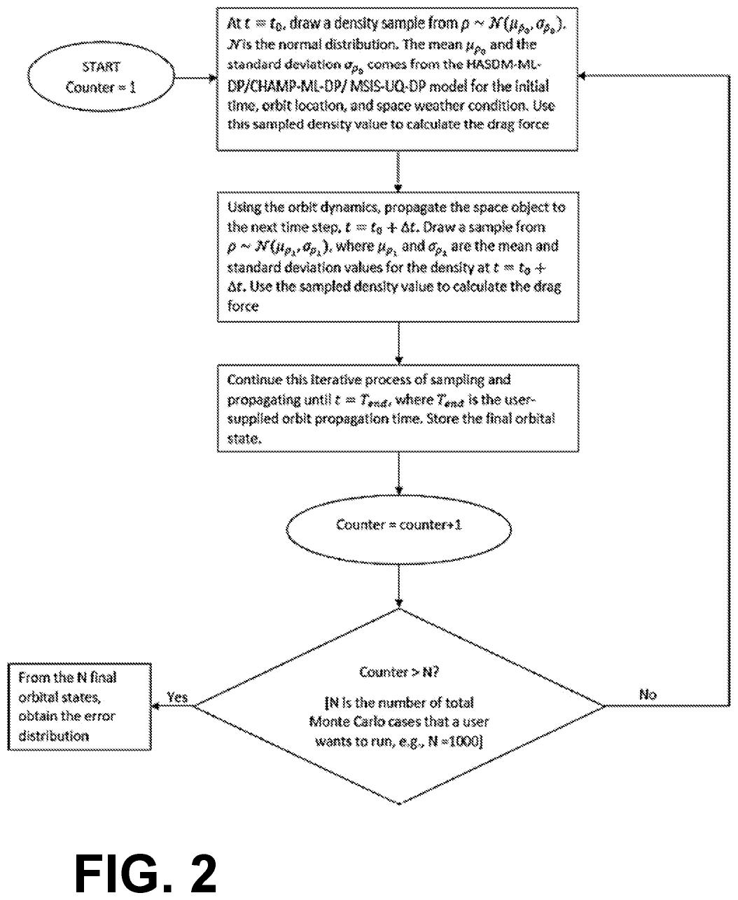

Orbital parameters and measurements have uncertainties, which are expressed using PDFs derived from some mathematical model or heuristics. In a Monte Carlo method, one repeatedly samples from the PDF representing the uncertainty and carries out orbit propagation to construct a population of objects, from which statistical information about their states can be obtained. The schematic of a ‘traditional’ Monte Carlo approach to orbit uncertainty propagation in the presence of atmospheric density uncertainties is shown in FIG. 2. In the traditional approach, the sampling frequency, which is defined as the inverse of Δt in FIG. 2, is high. This high sampling frequency leads to partial ‘cancellation’ of the (drag) perturbation effects, resulting in unrealistically small orbit errors. To explain the ‘cancellation’ effect, let us consider a hypothetical case of Δt=1 s and a constant density field with normal distribution [symbol] (10⁻¹² kg/m³, 10⁻¹³ kg/m³). A series of sampled density values at four consecutive time steps 0 s, 1 s, 2 s, 3 s can be 0.94×10⁻¹² kg/m³, 1.07×10⁻¹² kg/m³, 0.98×10⁻¹² kg/m³, and 1.01×10⁻¹² kg/m³, respectively. The drag force with a density greater than the mean value will increase the along-track error, and the drag force with a density smaller than the mean value will decrease the along-track error. Without a sufficiently large Δt, the two perturbation effects partially cancel out each other. Such behavior is unrealistic as actual density values have spatiotemporal correlation, i.e., the change in density should be more gradual. In the later part of this disclosure, an orbit uncertainty propagation scenario is simulated using the traditional Monte Carlo method.

### Modified Monte Carlo Simulation Techniques for Density Correlation

The atmospheric density is correlated in both time and space. The sampling procedure for the traditional Monte Carlo scheme needs to be modified to correctly capture the effect of this correlation on the evolution of orbital state uncertainty. In various examples, two Monte Carlo schemes based on the sampling of so-called ‘bias’ factor κ are presented. If κᵢ is a sampled value of the bias factor at any point in the orbit for a Monte Carlo run, then the corresponding density sample is ρᵢ=μ_{ρ}_{ᵢ}+κᵢσ_{ρ}_{ᵢ}, where the mean density μ_{ρ}_{ᵢ} and the standard deviation σ_{ρ}_{ᵢ} are obtained from the HASDM-ML-DP, CHAMP-ML-DP, MSIS-UQ-DP or other density model. When computed across all Monte Carlo runs, the bias factor needs to have the following properties for each epoch of the orbit propagation—(a) E[κ] is roughly equal to zero, (b) Var[κ] is roughly equal to unity, where E[⋅] represents the expected value and Var[⋅] represents the variance. These two desirable properties of the bias factor ensures that the machine learning model predicted moments are preserved, i.e., E[ρ]=E[μ_{ρ}_{ᵢ}+κσ_{ρ}_{ᵢ}] is roughly equal to the model predicted mean μ_{ρ}_{ᵢ} and Var[ρ]=Var[μ_{ρ}_{ᵢ}+κσ_{ρ}_{ᵢ}] is roughly equal to the model predicted variance σ_{ρ}_{ᵢ}².

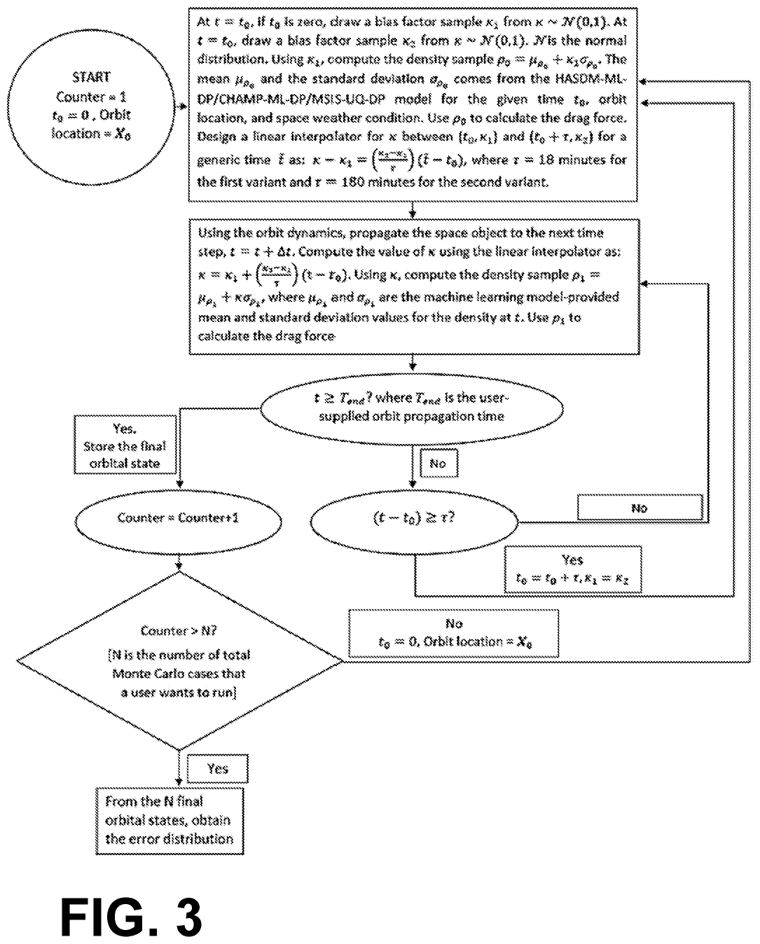

In the first proposed Monte Carlo method, K is sampled from a standard normal distribution. Two variants of this method are implemented—(1) first variant: for each Monte Carlo run, K was sampled every 18 minutes and the value of κ was interpolated in between, (2) second variant: for each Monte Carlo run, K was sampled every 180 minutes and the value was interpolated in between. A detailed schematic of the first proposed Monte Carlo method is shown in FIG. 3.

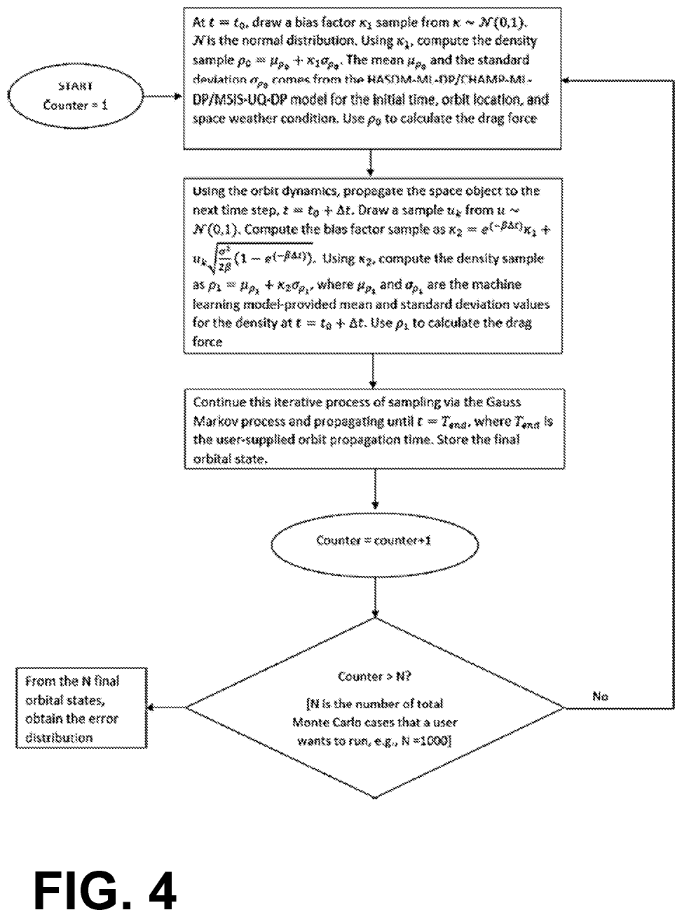

In the second proposed Monte Carlo method, K is sampled from a first order Gauss-Markov process:

$$κ ( t + Δ t ) = exp ( - β Δ t ) κ ( t ) + {u}_{k} ( t + Δ t ) \sqrt{\frac{{σ}^{2}}{2 β} ( 1 - exp ( - 2 β Δ t ) )} \qquad ( 4 a )$$

$$β = - \frac{ln 0.5}{τ} \qquad ( 4 b )$$

where uₖ(t+Δt) is a random number sampled from the standard normal distribution. The factor (σ²/(2β)), which represents the steady-state variance of κ, is taken to be unity. The parameter τ is the “half-life” and governs the rate at which the auto-correlation fades. In various examples, two variants of the second Monte Carlo method were implemented —(1) half-life τ is taken to be 18 minutes, (2) half-life τ is taken to be 180 minutes. FIG. 4 shows the detailed schematic for the second Monte Carlo approach.

A 3-day orbit propagation was simulated using various Monte Carlo schemes discussed so far to examine the along-track position error between the mean orbit (i.e., the orbit propagated with mean density) and the Monte Carlo runs. For each Monte Carlo method, a total of 1000 Monte Carlo iterations was used. The initial epoch for the simulation is taken as 01:00:00 UTC, Sep. 7, 2002, which corresponds to a geomagnetic storm from the solar cycle 23. A high-inclination LEO orbit was used and no initial uncertainty in the position or velocity was assumed. The initial orbit state is taken as X₀=[3782900.7032 m, −5441600.6779 m, −1420075.1327 m, −606.6600 m/s, 1539.2559 m/s, −7488.3946 m/s] in the Earth-centered inertial (ECI) frame. Apart from the central Earth gravity, only the dominant J₂ and atmospheric drag perturbations are considered for the orbit propagation, where the atmospheric density is modeled using the stochastic HASDM-ML-DP model. The object is assumed to be spherically symmetric with a cross-sectional area-to-mass ratio (AMR) value of 0.0015 m²/kg and drag coefficient C_{D}_{_{HASDM}} value of 3.0912.

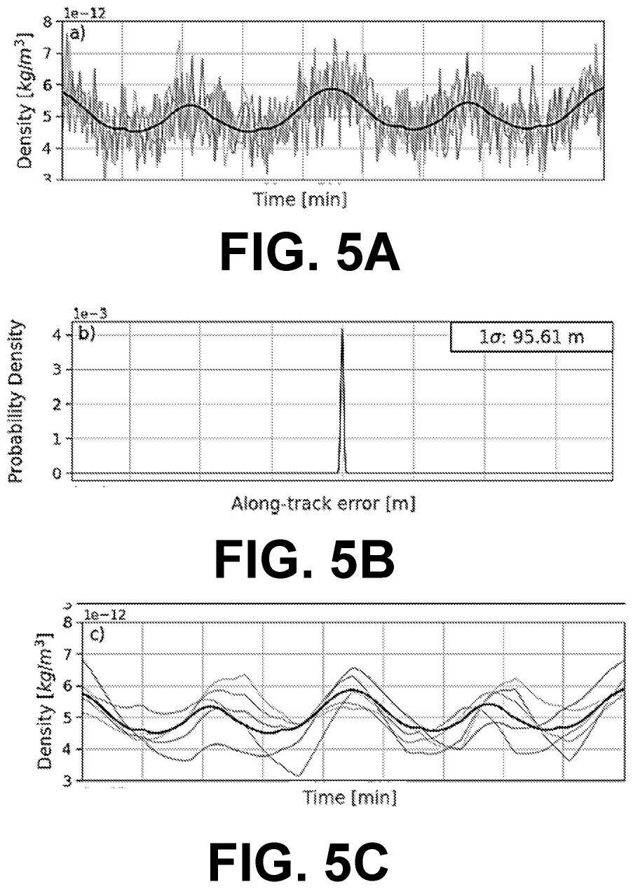

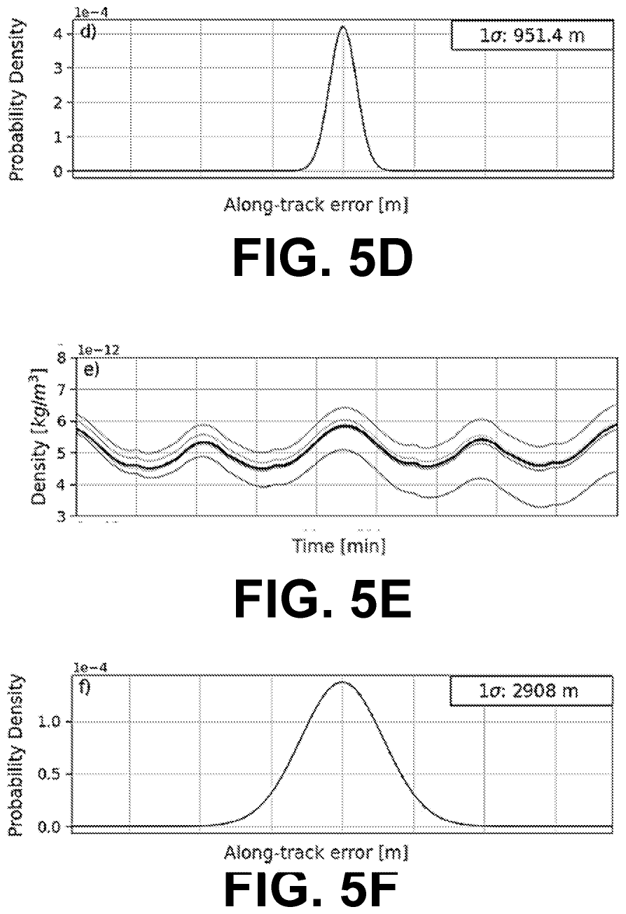

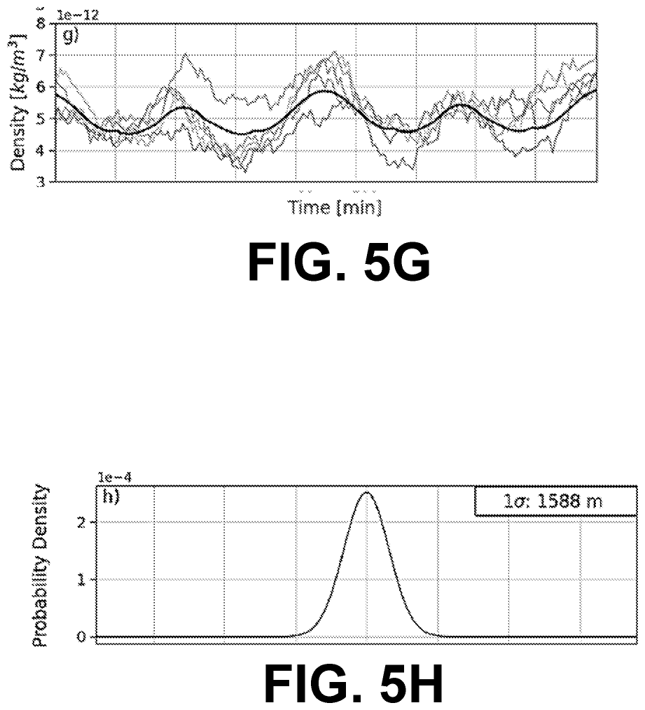

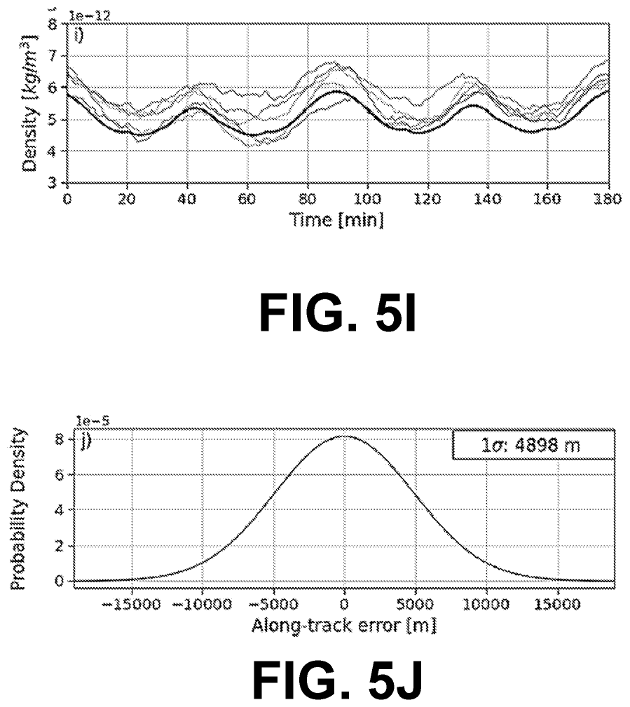

FIGS. 5A-5J shows a comparison of the different Monte Carlo methods. FIGS. 5A, 5C, 5E, 5G, and 5I show the density values for the first three hours of the propagation. The bold black curve in the density plots is the mean density curve, and the five colored curves correspond to the first five Monte Carlo iterations. FIGS. 5B, 5D, 5F, 5H, and 5J show the normal PDF for the along-track error at the end of three-day propagation. FIGS. 5A and 5B correspond to the traditional Monte Carlo method, FIGS. 5C and 5D correspond to the modified Monte Carlo method 1 with K=18 minutes, FIGS. 5E and 5F correspond to the modified Monte Carlo method 1 with K=180 minutes, FIGS. 5G and 5H correspond to the modified Monte Carlo method 2 with a half-life of 18 minutes, and FIGS. 5I and 5J correspond to the modified Monte Carlo method 2 with a half-life of 180 minutes. For the traditional Monte Carlo method, as seen in FIG. 5A, the density variations have little to no spatiotemporal correlation, resulting in a small standard deviation of 95.61 m for the along-track error. As K increases for the modified Monte Carlo method 1, the along-track error (standard deviation value) increases from 951.4 m to 2908 m, as a larger K leads to a stronger spatiotemporal correlation of the density, allowing the orbital errors to grow more in between two sampling times. Similarly, for the modified Monte Carlo method 2, as the half-life increases from 18 minutes to 180 minutes, the along-track error (standard deviation value) increases from 1588 m to 4898 m. A larger half-life means a stronger spatiotemporal density correlation. Monte Carlo method 2 with an 18-minute half-life is assumed to be the most realistic.

### The Consider Covariance Sigma Point (CCSP) Filter

The Monte Carlo simulation method is probably the most well-known method for orbit uncertainty propagation. With a sufficiently large number of samples, the method can capture the evolution of any higher-order moments. However, the computing costs are substantial, especially if the goal is to propagate uncertainty in tens of thousands of catalog objects for conjunction assessment over a period of several days or more. An alternative method for orbit uncertainty propagation—one that is computationally cheap and often used in space operations—is the extended Kalman filter (EKF) for linear uncertainty propagation. For highly non-linear systems, the unscented Kalman filter (UKF) is a more accurate and convenient alternative to the prevalent EKF because it does not make any linearization approximations, nor does it require the computation of the Jacobian matrices. The UKF relies on non-linear propagation of a select number of the so-called sigma points, which are carefully selected to capture the first two moments. The Kalman filtering techniques typically have two steps—a propagation step and an update step. The computations in the update step rely on sensor measurements.

There is no direct method to translate the epistemic uncertainty predicted by the HASDM-ML-DP/CHAMP-ML-DP/MSIS-UQ-DP models in atmospheric density to the uncertainty in orbital states (position, velocity) under a traditional EKF/UKF framework. A consider covariance analysis based propagation of sigma points can address the issue of translating atmospheric density model uncertainty to uncertainty in state estimates. In various examples of the present disclosure such a framework is referred to as the consider covariance sigma point (CCSP) filter. Next, the methodological procedure for the implementation of the CCSP filter for orbit uncertainty propagation for the first two-time steps is discussed.

The state X of interest for the orbit dynamical equations consists of the space object position and velocity, augmented by the atmospheric density, which is the “consider parameter”:

X=[xyzvₓv_{y}v_{z}ρ]^{T} (5)

where x, y, z are the Cartesian position coordinates, vₓ, v_{y}, v_{z} are the Cartesian velocity coordinates, and ρ is the atmospheric density.

### Computations for t₀

At the initial time (i.e., t=0 or t₀), we no uncertainty in the position and velocity (modeled by numbers ϵᵢ that are very small and arbitrarily close to zero) is assumed, and the density uncertainty σ_{ρ}_{₀}² is estimated from the HASDM-ML-DP/CHAMP-ML-DP/MSIS-UQ-DP models. The initial cross-correlation between different states to be zero. Mathematically, the following equations for the initial mean state and the covariance matrix are:

Xₜ₌₀=[x₀y₀z₀vₓ_{₀}v_{y}_{₀}v_{z}_{₀}ρ₀]^{T} (6a)

Pₓ_{ₜ₌₀}=Diag([ϵₓ²ϵ_{y}²ϵ_{z}²ϵvₓ²ϵv_{y}²ϵv_{z}²ρ_{ρ}_{₀}²]) (6b)

where Diag represents the diagonal matrix. As a useful rule of thumb, ϵᵥ_{ᵢ}² are smaller than ϵₓ², ϵ_{y}², ϵ_{z}².

To facilitate the computation of the sigma points, a scaled lower-triangular block-Cholesky decomposition of the initial covariance matrix is computed as:

$${S}_{{X}_{t = 0}} = [ \begin{matrix}\sqrt{{λ}_{1} + n} Chol ( {[ {P}_{{X}_{t = 0}} ]}_{( 1 : n ) , ( 1 : n )} ) & {0}_{n \times p} \\ {0}_{p \times n} & \sqrt{{λ}_{2} + p} {σ}_{{ρ}_{0}}\end{matrix} ] \qquad ( 7 )$$

where Chol(⋅) computes the Cholesky decomposition of the argument matrix and can be computed using Python's Numpy package (NumPy linear algebra function numpy.linalg.cholesky). The notation [⋅]_{(1:n),(1:n)} denotes the submatrix consisting of the first n rows and first n columns of the argument matrix. Parameter n is the dimension of the non-augmented state, i.e., n=6, parameter p is the dimension of the consider parameter, i.e., p=1, λ₁ and λ₂ are scaling parameters such that λ₁+n=3 and λ₂+p=3, 0_{n×p} denotes the n×p all-zero matrix, and 0_{p×n} denotes the p×n all-zero matrix.

Using the Sₓ_{ₜ₌₀} matrix, two sets of sigma points are computed. The first set, comprising 2n+1 sigma points (13 sigma points), is given by:

[symbol]

₍ᵢ₎_{ₜ₌₀}=Xₜ₌₀ where i=0 (8a)

[symbol]

₍ᵢ₎_{ₜ₌₀}=Xₜ₌₀+[S_{X}_{ₜ₌₀}]ᵢ where i=0 (8b)

[symbol]

₍ᵢ₊ₙ₎_{ₜ₌₀}=Xₜ₌₀−[S_{X}_{ₜ₌₀}]ᵢ where i=0 (8c)

where [⋅]ᵢ represents the i^{th} column of the argument matrix.

The second set, comprising 2p+1 sigma points (3 sigma points), accounts for the uncertainty in the consider parameter ρ and is given by:

x₍ᵢ₎_{ₜ₌₀}=Xₜ₌₀ where i=0 (9a)

x₍ᵢ₎_{ₜ₌₀}=Xₜ₌₀+[S_{X}_{ₜ₌₀}]ₙ₊ᵢ where i=1:p (9b)

x₍ᵢ₊ₚ₎_{ₜ₌₀}=Xₜ₌₀−[S_{X}_{ₜ₌₀}]ₙ₊ᵢ where i=1:p (9c)

where, for the orbit propagation problem, [S_{X}_{ₜ₌₀}]ₙ₊ᵢ=[S_{X}_{ₜ₌₀}]ₙ₊ₚ is the last column of S_{X}_{ₜ₌₀} matrix.

The first set of thirteen (13) sigma points and the second set of three sigma points are then propagated from the initial time to the next time step (t=t₀+Δt) using perturbed two-body dynamics to obtain

$${𝒳}_{{( i )}_{t = {t}_{0} + Δ t}} and {x}_{{( i )}_{t = {t}_{0} + Δ t}} ,$$

respectively. Only the dominant J₂ and atmospheric drag perturbations are considered in this disclosure.
Computations for t₀+Δt

At t=t₀+Δt, the first step involves estimating the mean and the covariance matrix from the propagated sigma points using a weighted averaging method. The mean and the covariance matrix from the first set of sigma points are computed as:

$${X}_{𝒳 , t = {t}_{0} + Δ t} = {\sum }_{i = 0}^{2 n} [ {w}_{i}^{( mean )} {𝒳}_{{( i )}_{t = {t}_{0} + Δ t}} ] \qquad ( 10 a )$$

$${P}_{{X}_{𝒳 , t = {t}_{0} + Δ t}} = {\sum }_{i = 0}^{2 n} [ {w}_{i}^{( cov )} ( {𝒳}_{{( i )}_{t = {t}_{0} + Δ t}} - {X}_{𝒳 , t = {t}_{0} + Δ t} ) {( {𝒳}_{{( i )}_{t = {t}_{0} + Δ t}} - {X}_{𝒳 , t = {t}_{0} + Δ t} )}^{T} ] \qquad ( 10 b )$$

where the weights are derived from the standard UKF framework and are obtained as:

$${w}_{0}^{( m e a n )} = {w}_{0}^{( c o v )} = \frac{{λ}_{1}}{n + {λ}_{1}} \qquad ( 11 a )$$

$${w}_{i}^{( m e a n )} = {w}_{i}^{( c o v )} = \frac{1}{2 ( n + {λ}_{1} )} where i = 1 : 2 n \qquad ( 11 b )$$

Similarly, the mean and the covariance matrix for the second set of 2p+1 propagated sigma points is computed using:

$${X}_{x , t = {t}_{0} + Δ t} = {\sum }_{i = 0}^{2 p} [ {ω}_{i}^{( mean )} {x}_{{( i )}_{t = {t}_{0} + Δ t}} ] \qquad ( 12 a )$$

$${P}_{{X}_{x , t = {t}_{0} + Δ t}} = {\sum }_{i = 0}^{2 p} [ {ω}_{i}^{( cov )} ( {x}_{{( i )}_{t = {t}_{0} + Δ t}} - {X}_{x , t = {t}_{0} + Δ t} ) {( {x}_{{( i )}_{t = {t}_{0} + Δ t}} - {X}_{x , t = {t}_{0} + Δ t} )}^{T} ] \qquad ( 12 b )$$

with weights obtained as:

$${ω}_{0}^{( m e a n )} = {ω}_{0}^{( c o v )} = \frac{{λ}_{2}}{p + {λ}_{2}} \qquad ( 13 a )$$

$${ω}_{i}^{( m e a n )} = {ω}_{i}^{( c o v )} = \frac{1}{2 ( p + {λ}_{2} )} where i = 1 : 2 p \qquad ( 13 b )$$

Following the computation of the consider covariance matrix

$${P}_{{X}_{x , t = {t}_{0} + Δ t}} ,$$

the n×p cross-correlation matrix is computed as:

$${P}_{c {ross}_{t = {t}_{0} + Δ t}} = {[ {P}_{{X}_{x , t = {t}_{0} + Δ t}} ]}_{( 1 : n ) , ( n + 1 : n + p )} \qquad ( 14 )$$

where the notation [⋅]_{(1:n),(n+1:n+p)} denotes the submatrix consisting of the first n rows and last p columns of the argument matrix.

From the cross-correlation matrix

$${P}_{{cross}_{t = {t}_{0} + Δ t}} ,$$

one can compute the additive uncertainty resulting from the inclusion of the consider parameter ρ as:

$$d {P}_{t = {t}_{0} + Δ t} = {P}_{{cross}_{t = {t}_{0} + Δ t}} ( \frac{1}{{σ}_{{ρ}_{1}}^{2}} ) {P}_{{cross}_{t = {t}_{0} + Δ t}}^{T} \qquad ( 15 )$$

where σ_{ρ}_{₁}² is the atmospheric density uncertainty estimate from the HASDM-ML-DP/CHAMP-ML-DP models computed at t=t₀+Δt at the mean position indicated by the first three coordinates of the vector [symbol] _{,t=t}_{₀}_{+Δt}.

The covariance matrix updated for the uncertainty in the consider parameter is then given as:

$${P}_{{X}_{t = {t}_{0} + Δ t}} = [ \begin{matrix}{[ {P}_{{X}_{𝒳 , t = {t}_{0} + Δ t}} ]}_{( 1 : n ) , ( 1 : n )} + {[ {dP}_{t = {t}_{0} + Δ t} ]}_{( 1 : n ) , ( 1 : n )} & {P}_{c {ross}_{t = {t}_{0} + Δ t}} \\ {P}_{c {ross}_{t = {t}_{0} + Δ t}}^{T} & {σ}_{{ρ}_{1}}^{2}\end{matrix} ] \qquad ( 16 )$$

A scaled lower-triangular block-Cholesky decomposition of the matrix

$${P}_{{X}_{t = {t}_{0} + Δ t}}$$

is then obtained as:

$${S}_{{X}_{t = {t}_{0} + Δ t}} = [ \begin{matrix}Chol ( A ) & {0}_{n \times p} \\ ( \frac{1}{\sqrt{{λ}_{2} + p} {σ}_{{ρ}_{1}}} ) {P}_{{cross}_{t = {t}_{0} + Δ t}}^{T} & \sqrt{{λ}_{2} + p} {σ}_{{ρ}_{1}}\end{matrix} ] \qquad ( 17 )$$

where the n×n matrix A is given by:

$$A = {( {λ}_{1} + n ) [ {P}_{{X}_{t = {t}_{0} + Δ t}} ]}_{( 1 : n ) , ( 1 : n )} - {B}^{T} B \qquad ( 18 a )$$

$$B = ( \frac{1}{\sqrt{{λ}_{2} + p} {σ}_{{ρ}_{1}}} ) {P}_{c {ross}_{t = {t}_{0} + Δ t}}^{T} \qquad ( 18 b )$$

Thereafter, using the

$${S}_{{X}_{t = {t}_{0} + Δ t}}$$

matrix, two sets of sigma points are computed. The first set of sigma points is given by:

$${𝒳}_{{( i )}_{t = {t}_{0} + Δ t}} = {X}_{𝒳 , t = {t}_{0} + Δ t} where i = 0 \qquad ( 19 a )$$

$${𝒳}_{{( i )}_{t = {t}_{0} + Δ t}} = {X}_{𝒳 , t = {t}_{0} + Δ t} + {[ {S}_{{X}_{t = {t}_{0} + Δ t}} ]}_{i} where i = 1 : n \qquad ( 19 b )$$

$${𝒳}_{{( i + n )}_{t = {t}_{0} + Δ t}} = {X}_{𝒳 , t = {t}_{0} + Δ t} - {[ {S}_{{X}_{t = {t}_{0} + Δ t}} ]}_{i} where i = 1 : n \qquad ( 19 c )$$

The second set of sigma points is given by:

$${x}_{{( i )}_{t = {t}_{0} + Δ t}} = {X}_{𝒳 , t = {t}_{0} + Δ t} where i = 0 \qquad ( 20 a )$$

$${x}_{{( i )}_{t = {t}_{0} + Δ t}} = {X}_{𝒳 , t = {t}_{0} + Δ t} + {[ {S}_{{X}_{t = {t}_{0} + Δ t}} ]}_{n + i} where i = 1 : p \qquad ( 20 b )$$

$${x}_{{( i + p )}_{t = {t}_{0} + Δ t}} = {X}_{𝒳 , t = {t}_{0} + Δ t} - {[ {S}_{{X}_{t = {t}_{0} + Δ t}} ]}_{n + i} where i = 1 : p \qquad ( 20 c )$$

Both sets of sigma points are then propagated to the next time step.

### Ensemble Modeling for Orbit Uncertainty Quantification

There is no evidence that any single atmospheric density model is always more accurate than alternative density models under all space weather conditions. As a result, drawing firm conclusions about orbital state uncertainties caused by atmospheric density uncertainties from a single density model is not recommended. According to various examples, the present disclosure relates to a multi-model ensemble approach where the final orbit state PDF is expressed as a combination of orbit state PDFs resulting from the individual HASDM-ML-DP, CHAMP-ML-DP, MSIS-UQ-DP, and/or other thermospheric density models. The approach is motivated by the ensemble approach commonly used in terrestrial weather forecasting; however, it is fundamentally different due to the inter-dependency between density and drag/ballistic coefficient. Because of the inter-dependency, the density outputs from different models cannot be simply combined and used in orbit predictions. The density from a given model needs to be effectively combined with the appropriate drag/ballistic coefficient for prediction, which is labeled as ‘advanced ensemble modeling.’ Although just three stochastic density models are discussed in detail in the disclosure, in various examples, the multi-model ensemble approach for orbit uncertainty quantification can be expanded to include any number of atmospheric density models. In some examples, an alternative input-based ensemble modeling technique can be used in which a single model is used, but the starting condition or driver input is perturbed to produce many outputs, which are then aggregated to provide the final uncertainty distribution. Next, the implementation of the proposed ensemble approach is described through an example.

Let us consider an LEO satellite A whose initial orbital state (Cartesian position and velocity components) is provided. The given state information consists of the initial mean and the covariance matrix. Furthermore, assume that the satellite has a constant cross-sectional area and a constant mass and that the atmosphere co-rotates with the Earth. As a first step for the ensemble approach, using the HASDM-ML-DP density model and the CCSP filter (or the Monte Carlo approach), let A be propagated over a user-defined period of choice. A constant value of drag coefficient C_{D}_{_{HASDM}} derived from a physical model is used for the propagation. In operational setups, ballistic coefficient (or drag coefficient if the cross-sectional area and mass are known) and atmospheric density are often estimated simultaneously to match the satellite observations (Eq. (1)), if available. In other words, if ρ₁ and ρ₂ are the density estimates from two different atmospheric density models and if CD₁ is the drag coefficient estimate corresponding to the first density model, then the “debiased” drag coefficient estimate CD₂ corresponding to the second density model is such that ρ₁CD₁=ρ₂CD₂. Debiasing can be done to simulate the coupling between orbit determination and orbit prediction. This little detour to explain the concept of debiasing is essential for the next step. As a second step for the ensemble approach, A can be propagated using the CHAMP-ML-DP density model for the same initial condition and the same period of time as earlier. The corresponding drag coefficient C_{D}_{_{CHAMP}} is obtained from a debiasing scheme based on the average ratio of densities predicted by the HASDM-ML-DP and CHAMP-ML-DP models along the orbit for a user-defined period before the initial epoch. As a third step for the ensemble approach, A can be propagated using the MSIS-UQ-DP density model for the same initial condition and time period as earlier. The corresponding drag coefficient C_{D}_{_{MSIS}} is obtained by a debiasing scheme based on the average ratio of densities predicted by the HASDM-ML-DP and MSIS-UQ-DP models along the orbit for a user-defined period before the initial epoch.

Let μ₁ and P₁ be the mean position and the covariance matrix representing positional uncertainty at the end of the propagation period using HASDM-ML-DP model. Let μ₂, P₂ represent the mean position and the covariance matrix at the end of the propagation period following CHAMP-ML-DP model. And, let μ₃, P₃ represent the mean position and the covariance at the end of the propagation using MSIS-UQ-DP model. In an ensemble formulation, the final PDF for the orbital position is given by an equally weighted Gaussian mixture as:

$$p ( 𝒳 ; {μ}_{1} , {P}_{1} , {μ}_{2} , {P}_{2} , {μ}_{3} , {P}_{3} ) = \frac{1}{3} N ( 𝒳 ; {μ}_{1} , {P}_{1} ) + \frac{1}{3} N ( 𝒳 ; {μ}_{2} , {P}_{2} ) + \frac{1}{3} N ( 𝒳 ; {μ}_{3} , {P}_{3} ) \qquad ( 21 )$$

where [symbol] (μᵢ, Pᵢ) represents the multivariate normal distribution with mean μᵢ and covariance Pᵢ.

### Results

Space weather has a strong influence on the propagation and prediction of orbital states. In this section, the evolution of orbital state uncertainty is investigated using the ensemble approach under four different space weather conditions:
1. Case-I: a geomagnetic storm during solar maximum (circa Sep. 7, 2002), which is refer to as ‘solar-max-storm’.
2. Case-II: a non-storm period during solar minimum (circa Dec. 2, 2009), which is refer to as ‘solar-min’.
3. Case-III: a simulated solar maximum scenario (circa Sep. 7, 2002) where the geomagnetic model drivers are kept constant at global mean values and all other drivers (e.g., solar flux values) have the same variations as that of case-I. The global mean values for the geomagnetic model drivers are obtained from the machine learning models' training data. This case is referred to as ‘solar-max-simulated’.
4. Case-IV: a simulated non-storm solar minimum case (circa Dec. 2, 2009) where the geomagnetic model drivers are kept constant at global mean values and all other drivers have the same variations as that of case-II. This case is referred to as ‘solar-min-simulated’.
   A 3-day orbit uncertainty propagation for a high-inclination LEO object is carried out for the four cases in the presence of J₂ and atmospheric drag orbital perturbations. The details of the simulations are given in Table 1.

TABLE 1
Simulation set-up for the orbit uncertainty
propagation using super-ensemble approach.

| Parameter | Value/Details |
|---|---|
| Initial position (ECI) | [3782900.7032, −5441600.6779, |
| | −1420075.1327] m |
| Initial velocity (ECI) | [−606.6600, 1539.2559, |
| | −7488.3946] m/s |
| Propagation period | 259200 s |
| Object shape/type | Spherical & symmetric |
| Cross-sectional AMR | .0015 m²/kg |
| Drag coefficient C_{D}_{_{HASDM}} | 3.0912 |
| Propagation period for debiasing | 8 hours |
| Initial epoch for case-I and case-III | 01:00:00 UTC, Sep. 7, 2002 |
| Initial epoch for case-II and case-IV | 00:00:00 UTC, Dec. 2, 2009 |
| Orbit propagation method | Modified Monte Carlo method 2 |
| | with half-life = 18 minutes |
| Number of Monte Carlo iterations | 1000 for each case for each density |
| | model |

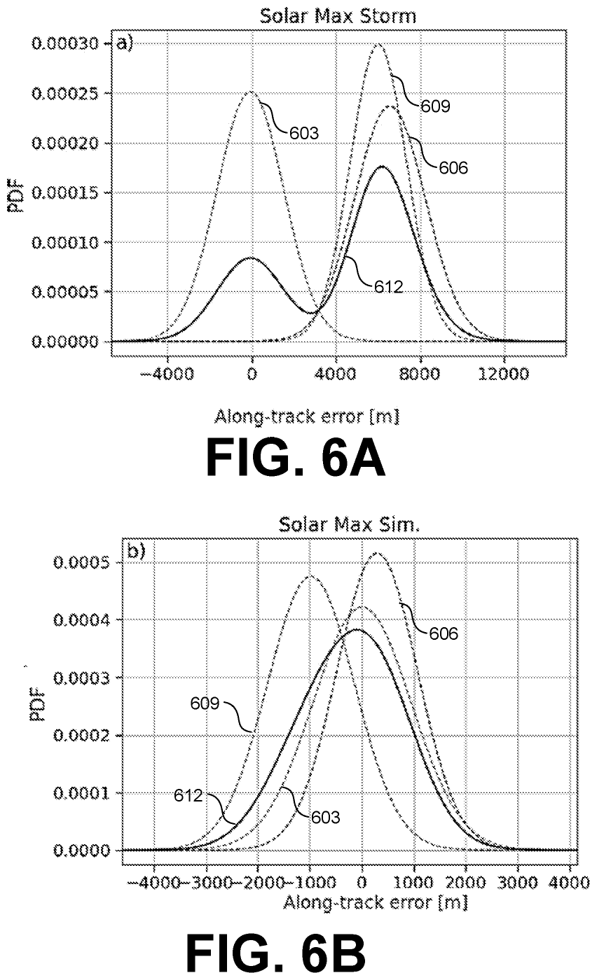

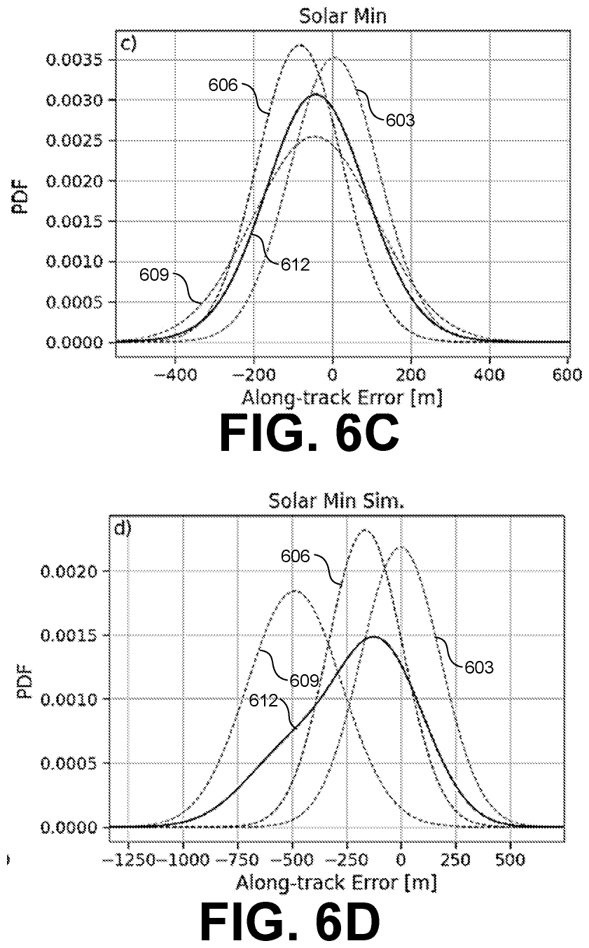

FIGS. 6A-6D illustrate the orbit state PDF for the along-track direction at the end of the 3-day propagation period. FIG. 6A quantifies the uncertainty in orbit state for the solar-max-storm case, FIG. 6B shows the orbit state distribution for the solar-max-simulated case, FIG. 6C shows the orbit state distribution for the solar-min case, and FIG. 6D shows the PDF for the solar-min-simulated case. In each of the figures, dashed curve 603 corresponds to the orbit state PDF for propagation using the HASDM-ML-DP model, the dashed curve 606 corresponds to the PDF for propagation using the CHAMP-ML-DP model, and the dashed curve 609 corresponds to the PDF for propagation using the MSIS-UQ-DP model. The term ‘scaled’ in the title indicates that the drag coefficients for the CHAMP-based and MSIS-based propagations are obtained by scaling the C_{D}_{_{HASDM}} using the debiasing scheme discussed earlier. The bold black curve 612 shows the resultant orbit state PDF from the super ensemble approach. When using more than one stochastic atmospheric density model, an ensemble technique unquestionably yields distributions that are capable of deviating greatly from the normal distribution that would otherwise be obtained. FIGS. 6A-6D show that the uncertainties for the solar maximum cases are larger compared to the solar minimum cases, highlighting the importance of the space weather condition in uncertainty quantification. For the solar-max-storm case, the ensemble approach leads to almost a bimodal uncertainty distribution, indicating the presence of two distinct regions of high probability for the orbit state. From the plot for the solar-max-simulated case, in the absence of geomagnetic variations, there is a reduced bias between the mean positions predicted by the HASDM-ML-DP and CHAMP-ML-DP models compared to the solar-max-storm case. As the geomagnetic variations are small in the solar minimum period, no such observation is made in comparison between solar-min-simulated and solar-min cases.

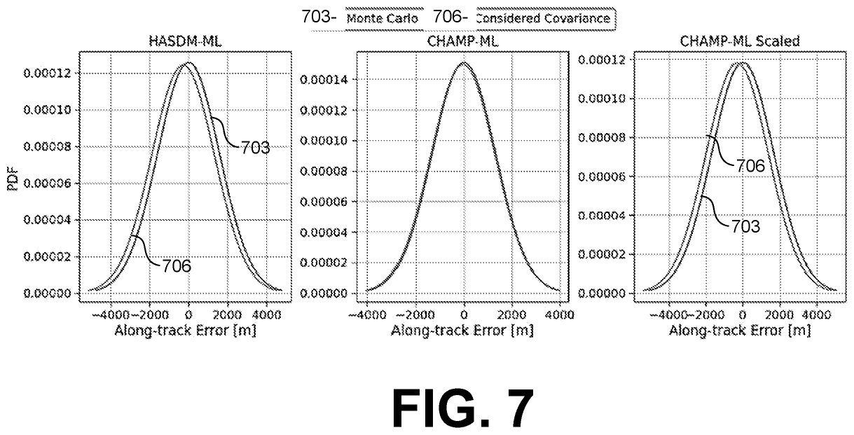

In addition to the results for the ensemble approach shown in FIGS. 6A-6D, a comparison between the Monte Carlo approach (modified Monte Carlo method 2 with a half-life of 18 minutes) and consider covariance approach to orbit uncertainty propagation is also demonstrated for a select few density models. FIG. 7 shows the orbit state PDF for the along-track direction for case-I, i.e., the solar-max-storm condition. The left figure corresponds to the propagation using the HASDM-ML-DP density model, the middle figure corresponds to the propagation using the CHAMP-ML-DP model using the drag coefficient C_{D}_{_{HASDM}} (i.e., no debiasing is performed), and the right figure corresponds to the propagation using CHAMP-ML-DP model using the drag coefficient obtained from the debiasing scheme. In each of the figures, the curve 703 corresponds to the Monte Carlo approach, and the curve 706 corresponds to the CCSP filter. Similar to the case of the traditional Monte Carlo approach, if the covariance update rate in the CCSP filter is high (Δt is small), the spatiotemporal density correlation is not captured correctly, resulting in unrealistically small uncertainty values. Based upon manual tuning, a covariance update rate of 60 minutes is used for the CCSP filter, where the density field varies according to the selected model between consecutive covariance updates. Clearly, from FIG. 7, the CCSP filter results and the Monte Carlo results are comparable with the added benefit of the CCSP filter being computationally much faster.

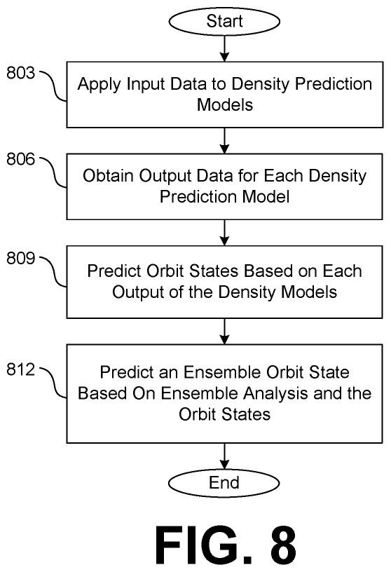

Referring next to FIG. 8, shown is a flowchart that provides one example of the operation of a portion of the orbit state prediction system 103. The flowchart of FIG. 103 provides merely an example of the many different types of functional arrangements that can be employed to implement the operation of the depicted portion of the orbit state prediction system 103. As an alternative, the flowchart of FIG. 8 can be viewed as depicting an example of elements of a method implemented within the computing environment of FIG. 1.

Beginning with block 803, the orbit state prediction system 103 can apply input data 106 as inputs to a plurality of density prediction models 112 (FIG. 1). In various examples, the input data can comprise solar indices/proxies (e.g., S₁₀, M₁₀, Y₁₀, F₁₀), geomagnetic indices (e.g., Ap, ap and Dst), temporal parameters (e.g., day of the year (doy), time of day (UT)), space weather parameters (e.g., velocity, temperature, etc.), and/or other inputs as can be appreciated. In various examples, these inputs can be extracted from the SET HASDM database, another database, and/or separately collected/calculated as can be appreciated. In various examples, the density prediction models can comprise stochastic density models configured to predict or otherwise estimated atmospheric density based at least in part on an analysis of the input data 106. For example, the density prediction models 112 can be HASDM-ML-DP, CHAMP-ML-DP, MSIS-UQ-DP, and/or other density prediction model.

At block 806, the orbit state prediction system 103 can obtain the output data for each of the density prediction models 112. In various examples, the output of each of the density prediction models 112 can comprise density data 121 (e.g., 121a, 121b, . . . 121N). In various examples, the density data 121 can comprise a density map, the mean and standard deviation of the atmospheric density, uncertainty density data, and/or other type of data representing the atmospheric density in view of an analysis of the input data 106.

At block 809, the orbit state prediction system 103 can predict a plurality of orbit states based on the density data 121 that is output from each of the density prediction models 112. In various examples, orbital propagation can be performed using each of the density prediction models 112 to predict orbit data 124 (e.g., orbit state PDF).

At block 812, the orbit state prediction system 103 can predict an ensembled orbit state 109 (e.g., ensembled orbit state PDF) based at least in part on an ensemble analysis of the orbit data 124. In various examples the orbit data 124 associated with each of the density models 112 can be combined via ensemble techniques to accurately predict the orbit state 109. In some examples, the ensemble analysis can correspond to a Gaussian mixture model and/or other type of ensemble tool for combining each of the orbit data 124 associated with the multi-model density analysis. Thereafter, this portion of the process proceeds to completion.

Correct quantification and propagation of orbital uncertainties are critical for space domain awareness and space traffic management functionalities. Uncertainty in atmospheric density modeling is one of the primary sources of uncertainty in orbit state prediction. Currently, most researchers propagate orbital uncertainties by considering uncertainty in atmospheric density model drivers and using a single density model.

In this disclosure, machine learning-based models that directly provide the epistemic uncertainty in the atmospheric density prediction are used. In various examples, three stochastic density models—HASDM-ML-DP, CHAMP-ML-DP, and MSIS-UQ-DP—are used to investigate the effect of atmospheric density uncertainty on the evolution of orbit state probability density function (PDF). The popular and traditional Monte Carlo approach for orbit uncertainty propagation fails to capture the spatiotemporal correlation of the atmospheric density. Therefore, in various examples, four modified Monte Carlo schemes, the first two based on the sampling and interpolation of the so-called bias factor from a normal distribution and the last two based on the first-order Gauss-Markov process, for orbit uncertainty propagation while successfully capturing the spatiotemporal density correlation. In some examples, since Monte Carlo methods are computationally expensive, a “consider covariance sigma point (CCSP)” filter can be used to perform orbit uncertainty propagation at a much smaller computational cost.

In various examples, the ensemble approach for predicting orbit state PDF that combines the uncertainty distributions predicted individually by each of the three stochastic density models is discussed. The super ensemble approach provides more realistic uncertainty estimates as no single density model is always more accurate across different regions of space and time. The three machine learning-based density models were developed using three different satellite data sources, each having unique advantages and disadvantages. In designing the super ensemble framework, appropriate drag coefficient values are used for each of the three density models. The drag coefficient value for the HASDM-ML-DP model is obtained from a physical model, the drag coefficient value for the CHAMP-ML-DP model is obtained from a debiasing scheme based on the average ratio of densities predicted by the HASDM-ML-DP and CHAMP-ML-DP models, and the drag coefficient value for the MSIS-UQ-DP model is obtained from a debiasing scheme based on the average ratio of densities predicted by the HASDM-ML-DP and MSIS-UQ-DP models. This debiasing scheme is incorporated to simulate the coupling between orbit determination and prediction.

To test the developed ensemble approach, a 3-day orbit propagation for a high inclination LEO object was simulated under four different space weather condition—(i) a geomagnetic storm during solar maximum, (ii) a non-storm condition with geomagnetic variations set to global mean values during solar maximum, (iii) a non-storm solar minimum period, and, (iv) a non-storm condition with geomagnetic variations set to global mean values during solar minimum. The ensemble approach can result in an orbit state PDF that can deviate significantly from a normal PDF resulting from a single density model. The spread in the PDF or uncertainties is much larger for solar maximum conditions as compared to the solar minimum conditions. Furthermore, the bias or difference between the mean positions predicted by different density models can be significantly influenced by geomagnetic variations that occur during a storm.

The developed ensemble framework of the present disclosure provides a novel and realistic way to model orbit uncertainties for satellite operations and the broader space weather community. The approach is highly adaptive, and can be easily expanded to include additional probabilistic atmospheric density models (e.g., TIE-GCM ROPE as discussed in Richard J. Licata*, Piyush M. Mehta. Reduced Order Probabilistic Emulation for Physics-based Thermosphere Models. Space Weather e2022SW003345, 21(5), 2023, which is incorporated by reference in its entirety herein).

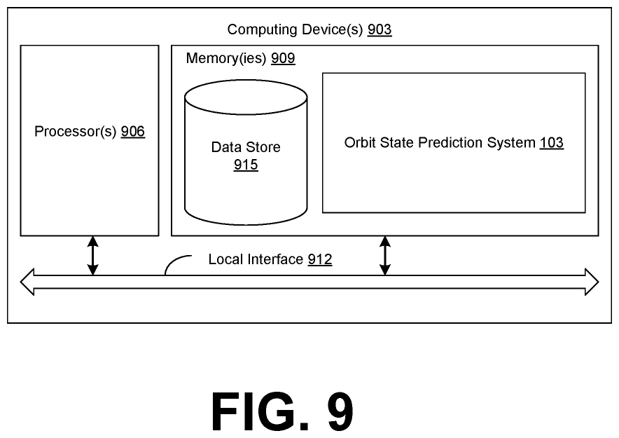

With reference now to FIG. 9, shown is one example of at least one computing device 903 (e.g., an interfacing device, central server, server, or other network device) that performs various functions of the orbit state prediction system 103 in accordance with various embodiments of the present disclosure. Each computing device 903 includes at least one processor circuit, for example, having a processor 906 and a memory 909, both of which are coupled to a local interface. To this end, each computing device 903 may be implemented using one or more circuits, one or more microprocessors, microcontrollers, application specific integrated circuits, dedicated hardware, digital signal processors, microcomputers, central processing units, field programmable gate arrays, programmable logic devices, state machines, or any combination thereof. The local interface 912 may comprise, for example, a data bus with an accompanying address/control bus or other bus structure as can be appreciated. Each computing device 903 can include a display for rendering of generated graphics such as, e.g., a user interface and an input interface such, e.g., a keypad or touch screen to allow for user input. In addition, each computing device 903 can include communication interfaces (not shown) that allows each computing device 903 to communicatively couple with other communication devices. The communication interfaces may include one or more wireless connection(s) such as, e.g., Bluetooth or other radio frequency (RF) connection and/or one or more wired connection(s).

Stored in the memory 909 are both data and several components that are executable by the processor 906. In particular, stored in the memory 909 and executable by the processor 906 is the space density prediction system 100, and/or other applications. Also stored in the memory 909 may be a data store 915 and other data. It is understood that there may be other applications that are stored in the memory 909 and are executable by the processor 906 as can be appreciated. Where any component discussed herein is implemented in the form of software, any one of a number of programming languages may be employed such as, for example, C, C++, C#, Objective C, Java®, JavaScript®, Perl, PHP, Visual Basic®, Python®, Ruby, Delphi®, Flash®, LabVIEW®, MATLAB® or other programming languages.

A number of software components are stored in the memory 909 and are executable by the processor 906. In this respect, the term “executable” means a program file that is in a form that can ultimately be run by the processor 906. Examples of executable programs may be, for example, a compiled program that can be translated into machine code in a format that can be loaded into a random access portion of the memory 909 and run by the processor 906, source code that may be expressed in proper format such as object code that is capable of being loaded into a random access portion of the memory 909 and executed by the processor 906, or source code that may be interpreted by another executable program to generate instructions in a random access portion of the memory 909 to be executed by the processor 906, etc. An executable program may be stored in any portion or component of the memory 909 including, for example, random access memory (RAM), read-only memory (ROM), hard drive, solid-state drive, USB flash drive, memory card, optical disc such as compact disc (CD) or digital versatile disc (DVD), floppy disk, magnetic tape, or other memory components.

The memory 909 is defined herein as including both volatile and nonvolatile memory and data storage components. Volatile components are those that do not retain data values upon loss of power. Nonvolatile components are those that retain data upon a loss of power. Thus, the memory 909 may comprise, for example, random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, the RAM may comprise, for example, static random access memory (SRAM), dynamic random access memory (DRAM), or magnetic random access memory (MRAM) and other such devices. The ROM may comprise, for example, a programmable read-only memory (PROM), an erasable programmable read-only memory (EPROM), an electrically erasable programmable read-only memory (EEPROM), or other like memory device.

Also, the processor 906 may represent multiple processors and the memory 909 may represent multiple memories that operate in parallel processing circuits, respectively. In such a case, the local interface 912 may be an appropriate network that facilitates communication between any two of the multiple processors, between any processor and any of the memories, or between any two of the memories, etc. The local interface 912 may comprise additional systems designed to coordinate this communication, including, for example, performing load balancing. The processor may be of electrical or of some other available construction.

Although the orbit state prediction system 103, and other various systems described herein may be embodied in software or code executed by general purpose hardware as discussed above, as an alternative the same may also be embodied in dedicated hardware or a combination of software/general purpose hardware and dedicated hardware. If embodied in dedicated hardware, each can be implemented as a circuit or state machine that employs any one of or a combination of a number of technologies. These technologies may include, but are not limited to, discrete logic circuits having logic gates for implementing various logic functions upon an application of one or more data signals, application specific integrated circuits having appropriate logic gates, or other components, etc. Such technologies are generally well known by those skilled in the art and, consequently, are not described in detail herein.

Also, any logic or application described herein, including the space density prediction system and/or application that comprises software or code can be embodied in any non-transitory computer-readable medium for use by or in connection with an instruction execution system such as, for example, a processor in a computer system or other system. In this sense, the logic may comprise, for example, statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system. The computer-readable medium can comprise any one of many physical media such as, for example, magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium may be a random-access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

Therefore, at least the following is claimed:

1. A system for accurately determining an orbit state of an orbiting object, comprising:
at least one computing device;
at least one application executable in the at least one computing device, wherein, when executed, the at least one application causes the at least one computing device to at least:
apply input data to a plurality of trained density prediction models to obtain atmospheric density data, each trained density prediction model of the plurality of trained density prediction models being configured to output respective atmospheric density data;
apply the atmospheric density data to an orbit propagator to predict a plurality of orbit states associated with the object, individual orbit states being associated with a respective trained density prediction model of the plurality of trained density prediction models; and
predict an orbit state of the orbiting object based at least in part on an ensemble analysis of the plurality of orbit states.

2. The system of claim 1, wherein the orbit state comprises a position and a velocity.

3. The system of claim 1, wherein the plurality of density prediction models comprise at least one of a high accuracy satellite drag model machine learning direct probability (HASDM-ML-DP) model, a challenging minisatellite payload machine learning direct probability (CHAMP-ML-DP) model, or a mass spectrometer-incoherent scatter uncertainty quantification direct probability (MSIS-UQ-DP) model.

4. The system of claim 1, wherein the input data comprises at least one of one or more solar indices, one or more geomagnetic indices, one or more space weather parameters, or one or more temporal parameters.

5. The system of claim 1, wherein a first subset of the input data is applied to a first density prediction model of the plurality of density prediction models, a second subset of the input data is applied to a second density prediction model of the plurality of density prediction models, and the first subset of the input data and the second subset of the input data differ.

6. The system of claim 1, wherein the orbital propagator is configured to analyze the atmospheric density data based at least in part on one of a monte carlo method or a consider covariance sigma point (CCSP) filter.

7. The system of claim 1, wherein the atmospheric density data comprises uncertainty estimates for density.

8. The system of claim 1, wherein individual orbit states of the plurality of orbit states associated with the object are based at least in part on the respective atmospheric density data and a respective drag or ballistic coefficient for individual density prediction models of the plurality of density prediction models.

9. The system of claim 8, wherein a first respective drag or ballistic coefficient associated with a first density prediction model differs from a second respective drag or ballistic coefficient associated with a second density prediction model.

10. The system of claim 1, wherein the ensemble analysis is based at least in part on a Gaussian mixture model.

11. A method for accurately determining an orbit state of an orbiting object, comprising:
applying, by at least one computing device, input data to a plurality of trained density prediction models to obtain atmospheric density data, each trained density prediction model of the plurality of trained density prediction models being configured to output respective atmospheric density data;
predicting, by the at least one computing device, a plurality of orbit states associated with the object based at least in part on the atmospheric density data and orbit propagation, individual orbit states being associated with a respective trained density prediction model of the plurality of trained density prediction models; and
predicting, by the at least one computing device, an orbit state of the orbiting object based at least in part on an ensemble analysis of the plurality of orbit states.

12. The method of claim 11, wherein the orbit state comprises a position and a velocity.

13. The method of claim 11, wherein the plurality of density prediction models comprise at least one of a high accuracy satellite drag model machine learning direct probability (HASDM-ML-DP) model, a challenging minisatellite payload machine learning direct probability (CHAMP-ML-DP) model, or a mass spectrometer-incoherent scatter uncertainty quantification direct probability (MSIS-UQ-DP) model.

14. The method of claim 11, wherein the input data comprises at least one of one or more solar indices, one or more geomagnetic indices, one or more space weather parameters, or one or more temporal parameters.

15. The method of claim 11, wherein a first subset of the input data is applied to a first density prediction model of the plurality of density prediction models, a second subset of the input data is applied to a second density prediction model of the plurality of density prediction models, and the first subset of the input data and the second subset of the input data differ.

16. The method of claim 11, wherein the orbital propagation is based at least in part on a monte carlo method or a consider covariance sigma point (CCSP) filter.

17. The method of claim 11, wherein the atmospheric density data comprises uncertainty estimates for density.

18. The method of claim 11, wherein individual orbit states of the plurality of orbit states associated with the object are based at least in part on the respective atmospheric density data and a respective drag or ballistic coefficient for individual density prediction models of the plurality of density prediction models.

19. The method of claim 18, wherein a first respective drag or ballistic coefficient associated with a first density prediction model differs from a second respective drag or ballistic coefficient associated with a second density prediction model.

20. The method of claim 11, wherein the ensemble analysis is based at least in part on a Gaussian mixture model.
